(19) United States
(12) Patent Application Publication
(10) Pub. No.: US 2025/0338504 A1
(43) Pub. Date: Oct. 30, 2025

(54) Topological Racetrack Memory having Multi-bits Storage Capability Each Unit Cell for In-memory Computing in Artificial Intelligent Inference Device

(71) Applicant: Aurora Micro Devices LLC, Emerald Hills, CA (US)

(72) Inventors: Kuok San Ho, Mountain Ranch, CA (US); Ming Jiang, San Jose, CA (US)

(73) Assignee: Aurora Micro Devices LLC, Emerald Hills, CA (US)

(21) Appl. No.: 18/645,369

(22) Filed: Apr. 25, 2024

(51) Int. Cl. H10B 61/00; G06F 12/02; H01F 10/32; H10N 50/01; H10N 50/10; H10N 50/85

(52) U.S. Cl. CPC H10B 61/00; G06F 12/023; H01F 10/3254; H01F 10/3272; H10N 50/01; H10N 50/10; H10N 50/85

(57) ABSTRACT

An apparatus and a fabricating method therefor of magnetic racetrack in-memory computing AI inference chip utilizing magnetic topological spin orbital torque (SOT) magnetic tunnel junction (MTJ) array unit cells comprises a SOT cell having laminated topological half Heusler alloy (THHA) layer, a MTJ cell having AP-pinned racetrack data storage layer, wherein the SOT and the magnetic racetrack data storage layer are configured to generate memory writing, the tunnel magnetoresistive (TMR) MTJ and the magnetic racetrack data storage layer are configured to provide memory reading, the magnetic racetrack data storage layer is configured to store multipolar bits through domain walls (DWs) which are driven to move together along the magnetic racetrack data storage layer by pulses of coherent spin-polarized electrical current, and together the SOT-MTJ cells having multi-bits data storage capability each cell are configuring a non-volatile memory array to store a corresponding programmable weight matrix for AI in-memory computing.

### CROSS REFERENCE TO RELATED APPLICATIONS

Not Applicable.

### STATEMENT RE: FEDERALLY SPONSORED RESEARCH/DEVELOPMENT

Not Applicable.

### BACKGROUND

### Field of the Disclosure

The various aspects and embodiments described herein generally relate to a magnetic topological Racetrack in-memory computing artificial intelligence inference chip utilizing topological Heusler alloy SOT-MRAM array having magnetic racetrack data storage layer with multi-bits storage capability and a method of manufacturing processes and materials therefor.

### Description of the Related Art

Racetrack memory applications have been proposed for magnetoresistive random access memory (MRAM), employing the tunneling magnetoresistance (TMR) effect for data reading and the spin-transfer torque (STT) or spin orbit torque (SOT) effect for data writing. However, challenges in performance and reliability have emerged due to several factors: (1) significant demagnetization in the Magnetic Tunnel Junction (MTJ) data storage layer, leading to degradation of written bits over time, especially at high bit densities; (2) processing and manufacturing difficulties in maintaining the integrity of the storage layer, resulting in low yield, high costs, and reduced device reliability; (3) inefficient utilization of spin-orbit torque with conventional heavy metal materials, leading to high energy consumption and rendering the device unsuitable for edge applications; (4) low operating temperatures in topological insulator (TI) SOT due to the low melting point of topological insulator materials. These limitations present significant challenges in manufacturing large arrays of topological-based unit cells.

To address the need for enhanced long-term and thermal reliability while maintaining a large read-back signal-to-noise ratio (SNR) at high operating temperatures of topological-based AI inference devices, it is imperative to reduce the demagnetization field of the storage layer in the unit cell and significantly improve the melting point of TI materials in SOT cells. This can be achieved through the utilization of an anti-parallel pinned storage layer in conjunction with the deployment of topological half Heusler alloy (THHA) materials, further strengthened by employing partial milling and subsequent oxidation processes to enhance reliability and yield.

The implementation of an anti-parallel pinned (AP-pinned) storage layer serves to enhance long-term reliability and SNR by mitigating the effects of demagnetization on written bits, thereby reducing the occurrence of zigzag magnetic domains. Additionally, the incorporation of THHA materials, coupled with doping or cluster co-deposition with ceramic elements such as nitride, carbide, and oxide, or inert gases including N2, CO2, and O2, and further utilizing laminated THHA multilayer material structures, offers increased thermal stability margins and improved performance at elevated temperatures. These advancements are particularly critical in the context of high-volume manufacturing and hold the potential to enhance reliability while substantially reducing overall costs associated with AI device production.

### SUMMARY OF THE DISCLOSURES

The present disclosure generally relates to magnetic topological Heusler alloy SOT-MTJ unit cell comprising the MTJ cell having magnetic racetrack AP-pinned data storage layer having multi-bits storage capability and the SOT cell having laminated THHA multilayer, utilized for an in-memory computing AI inference chip, and a method of manufacturing processes and materials therefor.

In an aspect disclosed herein, an apparatus and a fabricating method therefor of magnetic racetrack in-memory computing AI inference chip utilizing magnetic topological SOT-MTJ array unit cells comprises a SOT cell having laminated THHA layer, a MTJ cell having AP-pinned racetrack data storage layer, wherein the SOT topological layer and the magnetic racetrack data storage layer are configured to generate memory writing, the TMR of a MTJ and the magnetic racetrack data storage layer are configured to provide memory reading, the magnetic racetrack data storage layer is configured to store multipolar bits through domain walls (DWs) which are driven to move together along the magnetic racetrack data storage layer by pulses of coherent spin-polarized electrical current, and together the SOT-MTJ cells having multi-bits data storage capability each cell are configuring a non-volatile memory array to store a corresponding programmable weight matrix for AI in-memory computing.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of an exemplary embodiment of a topological THHA SOT-TMJ unit cell having AP-Pinned racetrack data storage layer.

FIG. 2a is a schematic illustration of cross-sectional view of an exemplary embodiment of a process flow of fabricating racetrack STO-TMJ unit cell providing a topological SOT write cell providing SOT topological layer full film deposition, patterning through lithography and Ion Mill, dielectric material refill, and CMP.

FIG. 2b is a schematic illustration of a cross-sectional view of an exemplary embodiment of a process flow of fabricating racetrack STO-TMJ unit cell providing TMR full film deposition, hard mask (HM) patterning through lithography and RIE.

FIG. 2c is a schematic illustration of cross-sectional view of an exemplary embodiment of a process flow of fabricating racetrack STO-TMJ unit cell providing a MTJ patterning RIE and stop on MgO.

FIG. 2d is a schematic illustration of cross-sectional view of an exemplary embodiment of a process flow of fabricating racetrack STO-TMJ unit cell providing Ozone process then capped with isolation side gap.

FIG. 2e is a schematic illustration of cross-sectional view of an exemplary embodiment of a process flow of fabricating racetrack STO-TMJ unit cell providing a racetrack data storage layer patterning through lithography and Ion Mill.

FIG. 2f is a schematic illustration of cross-sectional view of an exemplary embodiment of a process flow of fabricating racetrack STO-TMJ unit cell providing a dielectric material refill, CMP liftoff with CMP stop layer, and Ion Mill and RIE with end point to final cap surface.

FIG. 2g is a schematic illustration of cross-sectional view of an exemplary embodiment of a process flow of fabricating racetrack STO-TMJ unit cell providing metal vias and connection layer.

FIG. 3 is a schematic illustration of cross-sectional view of an exemplary embodiment of a racetrack SOT-TMJ unit cell having laminated THHA multilayer SOT cell.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made ot embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

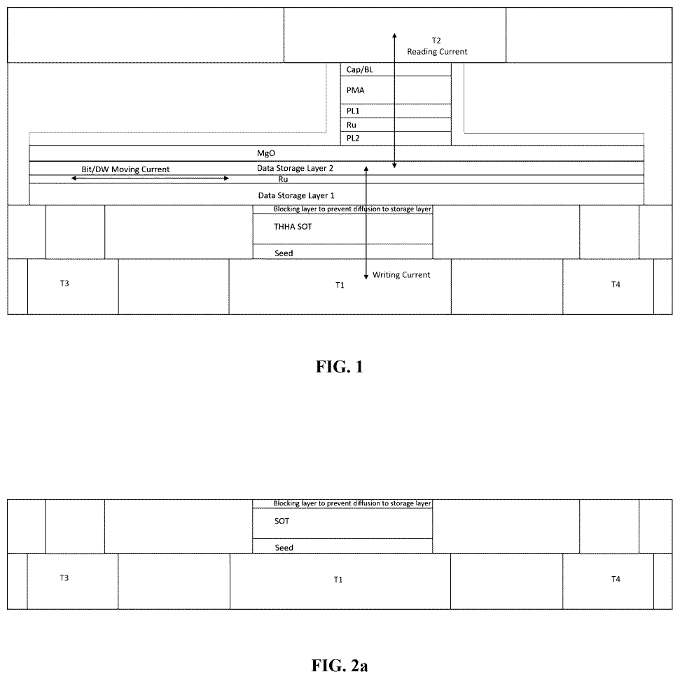

FIG. 1 is a schematic cross-sectional view of an exemplary embodiment of a topological THHA SOT-MTJ unit cell having AP-Pinned racetrack data storage layer. Embodiments of the present disclosure generally relate to an apparatus and a fabricating method therefor of the magnetic topological array unit cell comprising magnetic racetrack in-memory computing AI inference chip comprises: a spin orbit torque (SOT) cell configured from topological seed layer, topological layer, and blocking layer stack; a magnetic tunnel junction (MTJ) cell configured from tunneling magnetoresistance (TMR) layer stack; a magnetic racetrack data storage layer stack; and a fabricating method therefor comprising materials and manufacturable processes providing a racetrack SOT-MTJ cell configured the MTJ cell having AP-pinned racetrack data storage layer, and the SOT cell having laminated multilayer stack of topological seed layer, topological layer, and blocking layer, wherein the SOT topological layer and the magnetic racetrack data storage layer are configured to generate memory writing; the MTJ TMR and the magnetic racetrack data storage layer are configured to provide memory reading; the magnetic racetrack data storage layer is configured to store multipolar bits (multi-bits), wherein magnetic polarized pattern bits/domain walls (DWs) are used to store data, and driven to move together/along the magnetic racetrack data storage layer by pulses of coherent spin-polarized electrical current to push/move corresponding bit into read or write location; and together a magnetic chip comprising racetrack SOT-MTJ cells configuring a non-volatile memory array to store a corresponding programmable weight matrix provides in-memory computing for AI inference.

Each corresponding racetrack SOT-MTJ cell comprises 4 terminals: the writing is done by applied current between T1 and T4 to switch data storage layer the parallel and antiparallel states (referred to PL) by the SOT topological layer; the reading is done by the TMR between T1 and T3; the magnetic polarized pattern bits/domain walls (DWs) are used to store data and driven to move together/along the magnetic racetrack data storage layer by pulses of coherent spin-polarized electrical current to push/move corresponding magnetic bit into read or write location between T2 and T3; and the T1, T2, T3 and T4 terminals are metal lines comprising Al, Cu, and W, wherein Al, Cu, and W metal interconnection vias and lines form through photoresistor plating process or Damascene process.

The implementation of an anti-parallel pinned (AP-pinned) storage layer serves to enhance long-term reliability and SNR by mitigating the effects of demagnetization on written bits, thereby reducing the occurrence of zigzag magnetic domains. Additionally, the incorporation of THHA materials, coupled with doping or cluster co-deposition with ceramic elements such as nitride, carbide, and oxide, or inert gases including N2, CO2, and O2, and further utilizing laminated THHA multilayer material structures, offers increased thermal stability margins and improved performance at elevated temperatures. These advancements are particularly critical in the context of high-volume manufacturing and hold the potential to enhance reliability while substantially reducing overall costs associated with AI device production.

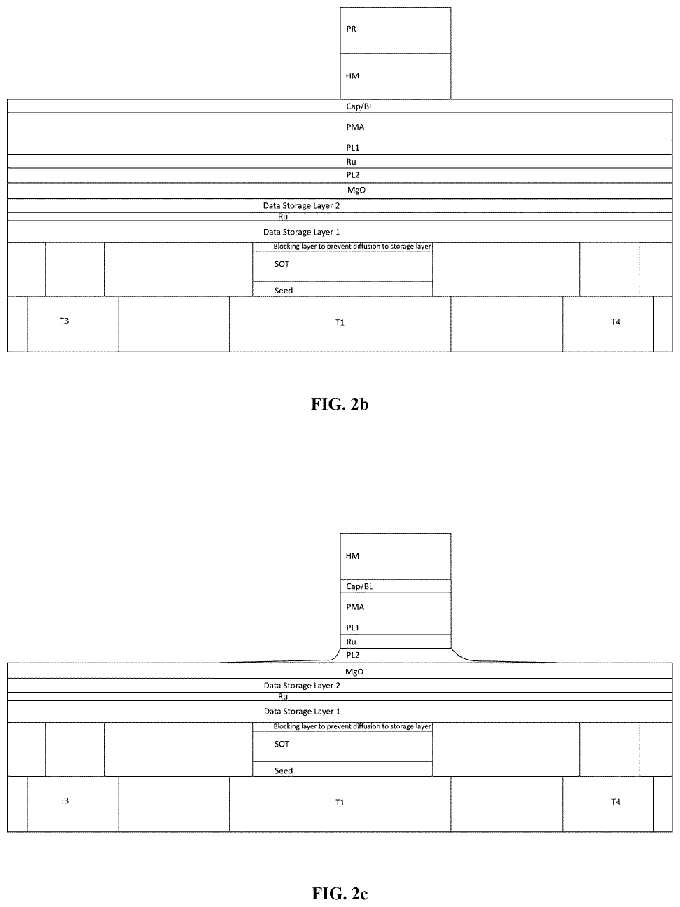

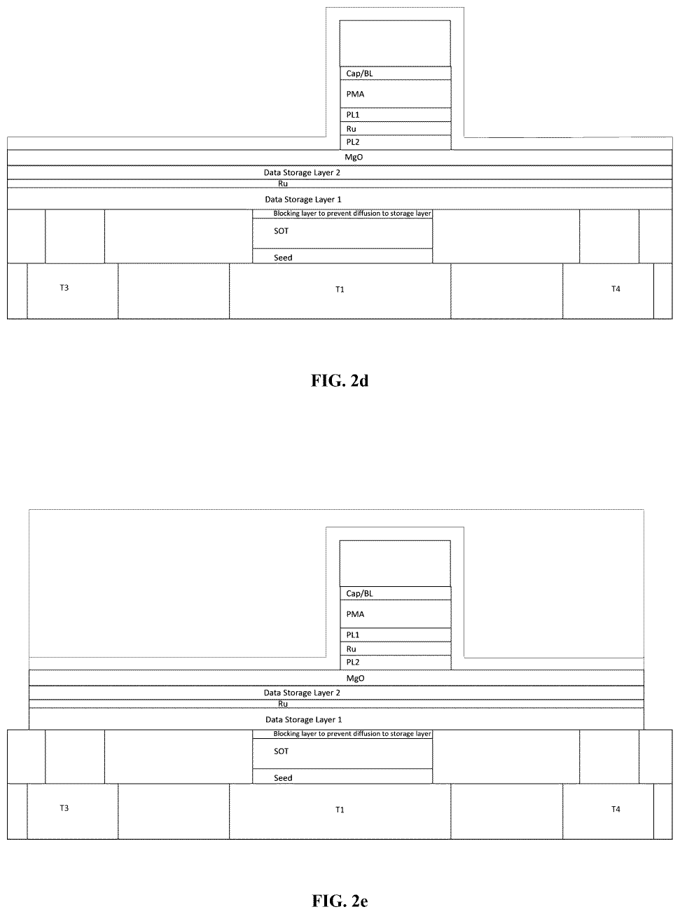

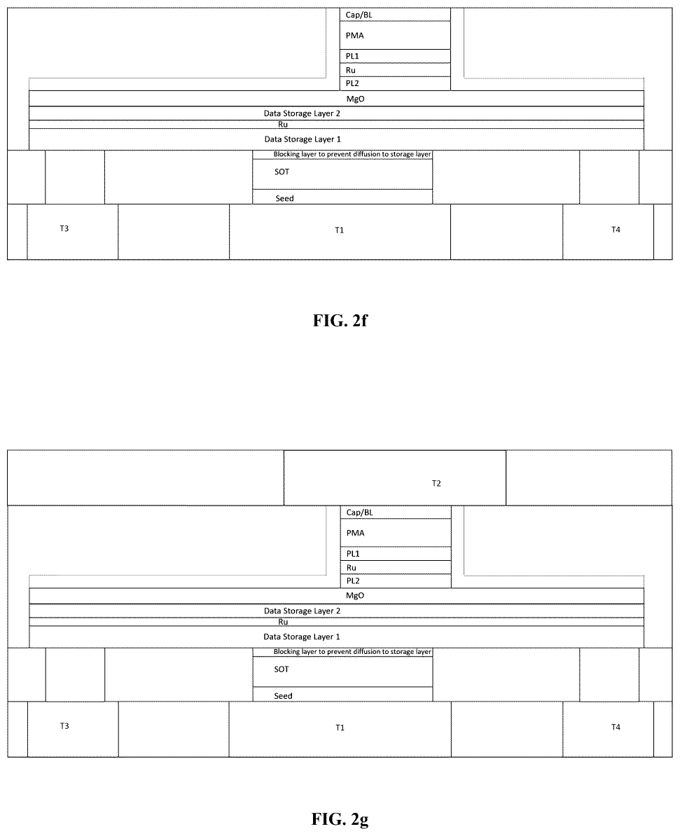

FIG. 2a is a schematic illustration of cross-sectional view of an exemplary embodiment of a process flow of fabricating racetrack STO-TMJ unit cell providing a topological SOT write cell providing SOT topological layer full film deposition, patterning through lithography and Ion Mill, dielectric material refill, and CMP including SOT topological seed/topological layer/blocking layer full film deposition, patterning through lithography and Ion Mill, dielectric film refill, and CMP liftoff with CMP stop layer, WTW thickness uniformity improvement with Ion Mill with endpoint, WIW thickness uniformity improvement with Focused Ion Scan Mill.

In one exemplary embodiment, topological layer may include but not limited to a topological half Heusler alloy (THHA) or a topological insulator (TI) or a mixture of THHA and TI layer. In one exemplary embodiment, each corresponding topological layer (SOT THHA) comprises topological half Heusler alloy (THHA) APtBi, wherein A comprises Y, Lu. In another exemplary embodiment, each corresponding topological layer (SOT THHA) comprises topological half Heusler alloy (THHA) BPdBi, wherein B comprises Y, Sm, Gd, Tb, Dy, Ho, Er, Tm, Lu. In another exemplary embodiment, each corresponding topological layer (TI SOT) of yet another exemplary embodiment comprises topological Insulator (TI) bismuth antimony BiSb and its compound CBiSb, wherein C comprises Ni.

In one exemplary embodiment, topological layer of yet another exemplary embodiment comprising doping or cluster co-depositing with ceramic elements including nitride, carbide, and oxide, or doping or cluster co-depositing with inert gases including N2, CO2, and O2 to prevent diffusion/migration and improve the melting temperature of THHA and TI materials therefore to improve the thermal and long-term reliability thus its operating temperature of the devices.

FIG. 2b is a schematic illustration of a cross-sectional view of an exemplary embodiment of a process flow of fabricating racetrack STO-TMJ unit cell providing TMR full film deposition, hard mask (HM) patterning through lithography and RIE providing a MTJ TMR full film deposition having seed layer/racetrack data storage layer/MgO/pin layer1/Ru/pin layer2/PMA layer/cap layer, wherein racetrack data storage layer has an anti-parallel pinned (AP-pinned) data storage layer1/Ru/data storage layer2 (Seed/SAF Storage layer/MgO/SAF Pin layer/PMA/Cap).

In one exemplary embodiment, each corresponding magnetic racetrack data storage layer comprises synthetic antiferromagnetic (SAF) anti-parallel (AP-pinned) data storage layer of an exemplary embodiment comprising CoFe/Ru/CoFe, CoFe/W/CoFe, CoFeB, CoFe/NiFe, Ta, MgO, W, CoHf, or combination and SAF.

In another exemplary embodiment, each corresponding TMR MTJ cell having Perpendicular Magnetic Anisotropy (PMA), wherein each corresponding p-MTJ cell comprises tunneling magnetoresistance (TMR) stack of an exemplary embodiment of seed layer/data storage layer1/Ru/data storage layer2/MgO/pin layer1/Ru/pin layer2/PMA layer/cap layer comprising Perpendicular Magnetic Anisotropy (PMA) layer comprises CrMo, FePt, CoPt, or combination; pin layer PL1/pin layer PL2 comprises CoFeB, CoFe/NiFe, Ta, CoHf, or combination; Ru thickness comprises 2-10A; data storage layer 1/data storage layer 2 providing magnetic data storage comprises CoFeB, CoFe/NiFe, Ta, MgO, W, CoHf, CoFe/Ru/CoFe, CoFe/W/CoFe or combination and SAF; MgO Barrier layer comprises crystalline orientation (001), thickness 2-40A, and device resistant 100-1000 Ohm; cap/seed/blocking layer (BL) providing texture and blocking diffusion to improve TMR ratio and topological Hall effect comprises Ta, Ru, Zr, Al, Ni, Co, Hf, MgO, or combinations thereof.

FIG. 2c is a schematic illustration of cross-sectional view of an exemplary embodiment of a process flow of fabricating racetrack STO-TMJ unit cell providing a MTJ patterning RIE and stop on MgO.

FIG. 2d is a schematic illustration of cross-sectional view of an exemplary embodiment of a process flow of fabricating racetrack STO-TMJ unit cell providing Ozone process then capped with isolation side gap layer providing stress and isolation of an exemplary embodiment comprising MgO, Al2O3, SiC, Si3N4, SiO2, SiOxNy, HfO2.

FIG. 2e is a schematic illustration of cross-sectional view of an exemplary embodiment of a process flow of fabricating racetrack STO-TMJ unit cell providing a racetrack data storage layer patterning through lithography and Ion Mill, wherein the data storage layer lengths and shapes can be adjusted by lithography masks including but not limited to I shape, L shape, U shape, and 3D.

FIG. 2f is a schematic illustration of cross-sectional view of an exemplary embodiment of a process flow of fabricating racetrack STO-TMJ unit cell providing a dielectric material refill, CMP liftoff with CMP stop layer, and Ion Mill and RIE with end point to final cap surface. FIG. 2g is a schematic illustration of cross-sectional view of an exemplary embodiment of a process flow of fabricating racetrack STO-TMJ unit cell providing metal vias and connection layer.

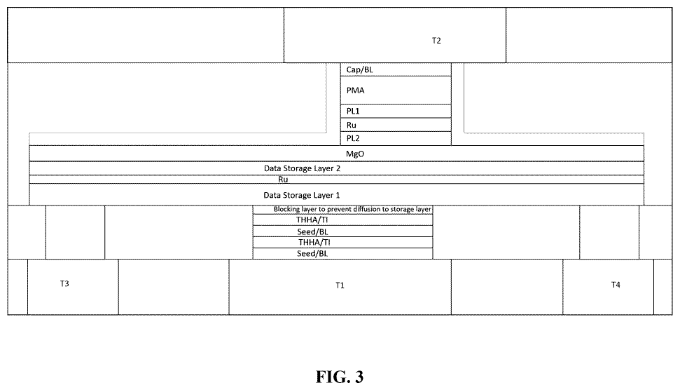

FIG. 3 is a schematic illustration of cross-sectional view of an exemplary embodiment of a racetrack SOT-TMJ unit cell having laminated THHA multilayer SOT cell comprising topological seed layer, topological layer SOT THHA, and blocking layer (BL), wherein the stack repeats one or more times.

In one exemplary embodiment, each topological seed/blocking layer (Seed/BL) providing texturing seed and blocking layer forming the epitaxial structure and promoting desired crystalline orientation and blocking diffusion of the topological layer of an exemplary embodiment comprises Cr, Ta, Ru, Ir, Pt, W, Zr, Al, Ni, Co, Hf, MgO, HfO2, or combinations thereof.

In one exemplary embodiment, each corresponding SOT cell comprises topological seed layer (Seed), topological layer SOT THHA, and blocking layer (BL) of an exemplary embodiment comprising laminated multilayer stack of topological seed layer, un-doped topological layer, and nitride, carbide and oxide doped or cluster co-deposited or/and N2, CO2, and O2 doped or cluster co-deposited topological layer, wherein the stack repeats one or more times, and each corresponding doped and un-doped topological layer of an exemplary embodiment comprising a topological half Heusler alloy (THHA) or a topological insulator (TI) or a mixture of THHA and TI layer, and blocking layer.

While the foregoing is directed to embodiments of the present disclosure, other and further embodiments of the disclosure may be devised without departing from the basic scope thereof, and the scope thereof is determined by the claims that follow.

What is claimed is:

1. An apparatus and a fabricating method therefor of the magnetic topological array unit cell comprising magnetic racetrack in-memory computing AI inference chip comprises:
a. a spin orbit torque (SOT) cell configured from topological seed layer, topological layer, and blocking layer stack;
b. a magnetic tunnel junction (MTJ) cell configured from tunneling magnetoresistance (TMR) layer stack;
c. a magnetic racetrack data storage layer stack;
d. and a fabricating method therefor comprising materials and manufacturable processes providing a racetrack SOT-MTJ cell configured the MTJ cell having AP-pinned racetrack data storage layer, and the SOT cell having laminated multilayer stack of topological seed layer, topological layer, and blocking layer, wherein:
e. the SOT topological layer and the magnetic racetrack data storage layer are configured to generate memory writing;
f. the MTJ TMR and the magnetic racetrack data storage layer are configured to provide memory reading;
g. the magnetic racetrack data storage layer is configured to store multipolar bits (multi-bits), wherein magnetic polarized pattern bits/domain walls (DWs) are used to store data, and driven to move together/along the magnetic racetrack data storage layer by pulses of coherent spin-polarized electrical current to push/move corresponding bit into read or write location;
h. and together a magnetic chip comprising racetrack SOT-MTJ cells configuring a non-volatile memory array to store a corresponding programmable weight matrix provides in-memory computing for AI inference.

2. A method of claim 1 for fabricating a SOT-MTJ cell having a racetrack data storage layer configuring a corresponding magnetic racetrack in-memory computing AI inference chip of an exemplary embodiment comprises:
a. providing a topological SOT write cell including SOT topological seed/topological layer/blocking layer full film deposition, patterning through lithography and Ion Mill, dielectric film refill, and CMP liftoff with CMP stop layer, WTW thickness uniformity improvement with Ion Mill with endpoint, WIW thickness uniformity improvement with Focused Ion Scan Mill;
b. providing a MTJ TMR full film deposition having seed layer/racetrack data storage layer/MgO/pin layer1/Ru/pin layer2/PMA layer/cap layer, wherein racetrack data storage layer has an anti-parallel pinned (AP-pinned) data storage layer1/Ru/data storage layer2 (Seed/SAF Storage layer/MgO/SAF Pin layer/PMA/Cap);
c. providing a TMR MTJ hard mask (HM) including hard mask full film deposition, hard mask patterning through lithography and RIE;
d. providing a MTJ patterning RIE and stop on MgO;
e. providing Ozone process then capped with isolation side gap layer;
f. providing a racetrack data storage layer patterning through lithography and Ion Mill, wherein the racetrack data storage layer lengths and shapes can be adjusted by lithography masks including but not limited to I shape, L shape, U shape, and 3-D;
g. providing a dielectric material refill, CMP liftoff with CMP stop layer, and Ion Mill and RIE with end point to final cap surface;
h. providing metal vias and connection layer.

3. A method of claim 1, wherein each corresponding TMR MTJ having side gap layer providing side stress and isolation of an exemplary embodiment comprising MgO, Al2O3, SiC, Si3N4, SiO2, SiOxNy, HfO2, or combinations thereof.

4. A method of claim 1, wherein each corresponding magnetic racetrack data storage layer comprises synthetic antiferromagnetic (SAF) anti-parallel (AP-pinned) data storage layer of an exemplary embodiment comprising CoFe/Ru/CoFe, CoFe/W/CoFe, CoFeB, CoFe/NiFe, Ta, MgO, W, CoHf, or combination and SAF.

5. The apparatus of claim 1, wherein each corresponding MTJ cell comprises an exemplary embodiment of Perpendicular Magnetic Anisotropy (PMA) TMR (p-MTJ).

6. The apparatus of claim 6, wherein each corresponding p-MTJ cell comprises tunneling magnetoresistance (TMR) stack of an exemplary embodiment of seed layer/data storage layer1/Ru/data storage layer2/MgO/pin layer1/Ru/pin layer2/PMA layer/cap layer comprising:
a. Perpendicular Magnetic Anisotropy (PMA) layer comprises CrMo, FePt, CoPt, or combination;
b. pin layer PL1/pin layer PL2 comprises CoFeB, CoFe/NiFe, Ta, CoHf, or combination;
c. Ru thickness comprises 2-10A;
d. data storage layer 1/data storage layer 2 providing magnetic data storage comprises CoFeB, CoFe/NiFe, Ta, MgO, W, CoHf, CoFe/Ru/CoFe, CoFe/W/CoFe or combination and SAF;
e. MgO Barrier layer comprises crystalline orientation (001), thickness 2-40A, and device resistant 100-1000 Ohm;
f. cap/seed/blocking layer (BL) providing texture and blocking diffusion to improve TMR ratio and topological Hall effect comprises Ta, Ru, Zr, Al, Ni, Co, Hf, MgO, or combinations thereof.

7. The apparatus of claim 1, wherein each corresponding SOT cell comprises a topological layer of an exemplary embodiment comprising topological half Heusler alloy (THHA) APtBi, wherein A comprises Y, Lu.

8. The apparatus of claim 1, wherein each corresponding SOT cell comprises a topological layer of another exemplary embodiment comprising topological half Heusler alloy (THHA) BPdBi, wherein B comprises Y, Sm, Gd, Tb, Dy, Ho, Er, Tm, Lu.

9. The apparatus of claim 1, wherein each corresponding SOT cell comprises a topological layer of yet another exemplary embodiment comprising topological insulator (TI) bismuth antimony BiSb and its compound CBiSb, wherein C comprises Ni.

10. The apparatus of claim 1, wherein each corresponding SOT cell comprises a topological layer of yet another exemplary embodiment comprising doping or cluster co-depositing having ceramic elements including nitride, carbide, and oxide, or doping or cluster co-depositing having inert gases including N2, CO2, and O2 to prevent diffusion/migration and improve the melting temperature of THHA and TI materials therefore to improve the thermal and long-term reliability thus its operating temperature of the devices.

11. The apparatus of claim 1, wherein each corresponding SOT cell comprises topological seed layer providing texturing to form the epitaxial structure and promote desired crystalline orientation and blocking layer (BL) blocking diffusion of the topological layer of an exemplary embodiment comprising Cr, Ta, Ru, Ir, Pt, W, Zr, Al, Ni, Co, Hf, MgO, HfO2, or combinations thereof.

12. The apparatus of claim 1, wherein each corresponding SOT cell comprises topological seed layer, topological layer, and blocking layer of an exemplary embodiment comprising laminated multilayer stack of topological seed layer, topological layer, and blocking layer, wherein the stack repeats one or more times.

13. The apparatus of claim 13, wherein each corresponding laminated multilayer stack of topological seed layer, topological layer, and blocking layer of an exemplary embodiment comprises topological seed, un-doped topological layer, and nitride, carbide and oxide doped or cluster co-deposited or/and N2, CO2, and O2 doped or cluster co-deposited topological layer, and blocking layer, wherein the stack repeats one or more times.

14. The apparatus of claim 14, wherein each corresponding doped and un-doped topological layer of an exemplary embodiment comprising a topological half Heusler alloy (THHA) or a topological insulator (TI) or a mixture of THHA and TI layer.

15. The apparatus of claim 1, wherein each corresponding racetrack SOT-MTJ cell comprises 4 terminals:
a. the writing is done by applied current between T1 and T4 to switch data storage layer the parallel and antiparallel states (referred to PL) by the SOT topological layer;
b. the reading is done by the TMR between T1 and T3;
c. the magnetic polarized pattern bits/domain walls (DWs) are used to store data and driven to move together/along the magnetic racetrack data storage layer by pulses of coherent spin-polarized electrical current to push/move corresponding magnetic bit into read or write location between T2 and T3;
d. and the T1, T2, T3 and T4 terminals are metal lines comprising Al, Cu, and W, wherein Al, Cu, and W metal interconnection vias and lines form through photoresistor plating process or Damascene process.
